(19) United States
(12) Patent Application Publication
(10) Pub. No.: US 2024/0297209 A1
(43) Pub. Date: Sep. 5, 2024

(54) FILM FORMING METHOD, METHOD OF MANUFACTURING SEMICONDUCTOR DEVICE, AND PROCESSING SYSTEM

(71) Applicant: Tokyo Electron Limited, Tokyo (JP)

(72) Inventor: Susumu YAMAUCHI, Yamanashi (JP)

(21) Appl. No.: 18/583,086

(22) Filed: Feb. 21, 2024

(30) Foreign Application Priority Data
Mar. 1, 2023 (JP) 2023-030784

(51) Int. Cl. H01L 21/02; C23C 16/30; C23C 16/34; C23C 16/40; C23C 16/455; C23C 16/56; H01L 21/3205

(52) U.S. Cl. CPC H01L 28/40; C23C 16/308; C23C 16/34; C23C 16/405; C23C 16/45527; C23C 16/56; H01L 21/02175; H01L 21/32051

(57) ABSTRACT

A film forming method includes: preparing a substrate on which a dielectric layer is formed in a processing container; forming a first metal oxide layer on the dielectric layer by supplying a first metal-containing precursor and a first oxygen gas; and forming a second metal oxide layer on the first metal oxide layer by supplying a second metal-containing precursor and a second oxygen gas different from the first oxygen gas.

### CROSS-REFERENCE TO RELATED APPLICATION

This application is based upon and claims the benefit of priority from Japanese Patent Application No. 2023-030784, filed on Mar. 1, 2023, the entire contents of which are incorporated herein by reference.

### TECHNICAL FIELD

The present disclosure relates to a film forming method, a method of manufacturing a semiconductor device, and a processing system.

### BACKGROUND

In a capacitor structure, as a method for reducing leakage current occurring at an interface between a capacitive film and an electrode, there is a method of inserting a thin film interface layer (hereinafter, also referred to as “ICL”) at an interface between opposite films. For example, Patent Documents 1 to 3 disclose that an interface layer is formed on a dielectric layer between metal layers by an atomic layer deposition (ALD) method or the like.

### PRIOR ART DOCUMENTS

### Patent Documents

Patent Document 1: Japanese Patent Laid-Open Publication No. 2013-131749
Patent Document 2: Japanese Patent Laid-Open Publication No. 2019-79907
Patent Document 3: Japanese Patent Laid-Open Publication No. 2022-85899

### SUMMARY

According to one embodiment of the present disclosure, there is provided a film forming method including: preparing a substrate on which a dielectric layer is formed in a processing container; forming a first metal oxide layer on the dielectric layer by supplying a first metal-containing precursor and a first oxygen gas; and forming a second metal oxide layer on the first metal oxide layer by supplying a second metal-containing precursor and a second oxygen gas different from the first oxygen gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating an example of a cross-sectional shape of a capacitor structure.

FIG. 2 is a diagram showing an example of results of ICL film formation according to an embodiment of the present disclosure.

FIG. 3 is a flowchart illustrating an example of a method of manufacturing a semiconductor device according to an embodiment of the present disclosure.

FIG. 4 is a view illustrating an example of a semiconductor device according to an embodiment of the present disclosure.

FIGS. 5A to 5C are diagrams illustrating examples of effects of an ICL film forming method according to an embodiment of the present disclosure.

FIG. 6 is a view illustrating an example of a processing system according to an embodiment of the present disclosure.

FIG. 7 is a view illustrating an example of a processing apparatus according to an embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each of the drawings, the same components may be denoted by the same reference numerals, and redundant descriptions thereof may be omitted.

### [Capacitor Structure]

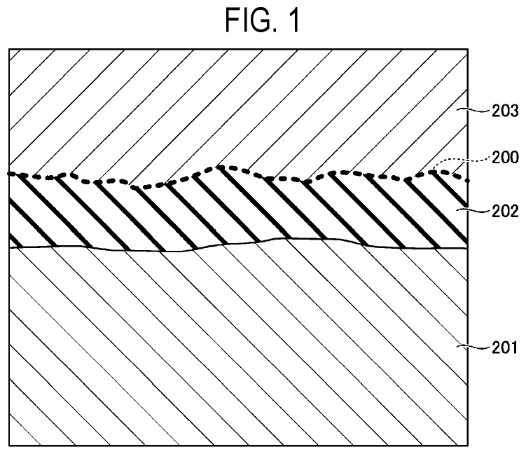

In the capacitor structure of a DRAM, charge is accumulated in a capacitive film (dielectric layer) interposed between electrodes, and the charge is injected and taken out by the electrodes. FIG. 1 is an elemental analysis view of a state of a cross-section of a portion of a capacitor by using an electron microscope.

A ZrO₂ layer 202 as a dielectric layer is formed between a TiN layer 201 as a lower electrode layer and a TiN layer 203 as an upper electrode layer. An extremely thin film ICL 200 serving as an interface layer is inserted at the interface between the ZrO₂ layer 202 of the dielectric layer and the TiN layer 203 of the upper electrode layer. In FIG. 1, the ICL 200 is highlighted with a dashed line. By inserting the ICL 200, leakage current generated between the ZrO₂ layer 202 of the dielectric layer and the TiN layer 203 of the upper electrode layer can be reduced.

The state of leakage current changes depending on the characteristics of the ICL 200, affecting the device characteristics of the capacitor. One of the causes that the leakage current is not reduced or is worse than the standard is deterioration in morphology or grain boundary in the ICL 200. The morphology indicates a smoothness of the interface of ICL 200, and leakage current can be reduced by forming the ICL 200 flat to reduce the morphology. In addition, the grain boundary indicates a smoothness of the interface between grains, that is, crystal grains, and leakage current can be reduced by reducing the grain boundary by making the grains (crystal grains) of ICL 200 smaller.

In the ICL 200, when the morphology is bad (large), the leakage current will be large, and when the morphology is good (small), the leak current will be small. In order to reduce the morphology of the ICL 200, it is important to form the ICL 200 under film forming conditions that allow the ICL 200 to be formed in an amorphous state and prevent the base layer, such as zirconia oxide (ZrO₂), from crystallizing.

After forming the ICL 200 in an amorphous state, a TiN layer 203 as an upper electrode layer is formed on the ICL 200, and then annealing is performed at a high temperature (e.g., about 430 degrees C.). By crystallizing the ICL 200 and its base layer through annealing, the ICL 200 with small morphology can be formed. As a result, a capacitor with reduced leakage current can be manufactured.

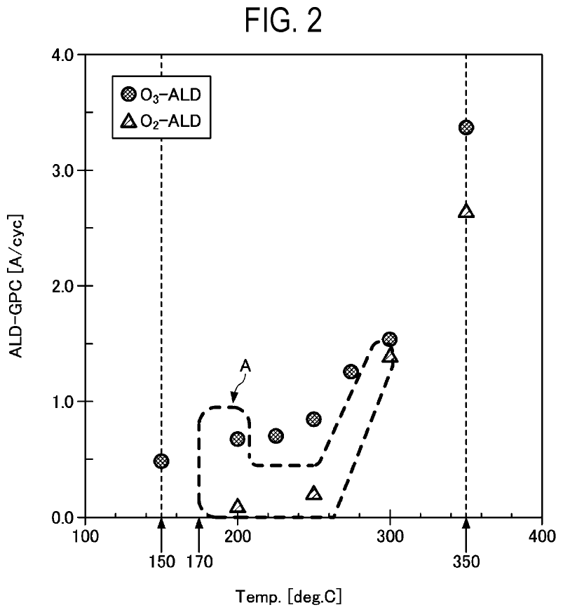

As film-forming conditions for forming the amorphous ICL 200 without crystallizing the base layer, a film forming temperature, a gas type, and a combination of gas types for the ICL 200 are important. FIG. 2 is a diagram illustrating an example of experimental results comparing deposition conditions of an ICL 200 according to an embodiment. The film forming conditions for the ICL 200 used in the experiment are shown below.

### <Film Forming Conditions>

Film forming temperature: 150 to 350 degrees C.
Gas type: ozone (O₃) or oxygen (O₂)
Precursor: molybdenum (Mo)
Pressure: 500 Pa

In addition, the film forming temperature is the temperature of the substrate or the temperature of the stage. The pressure refers to a pressure in the processing container.

For example, the ICL 200 is formed by supplying a Mo raw material (a Mo precursor) and O₃ gas or O₂ gas by an ALD method. In this case, one cycle including a process of adsorbing the Mo precursor onto the substrate, a process of purging with N₂ gas or the like, a process of supplying O₃ gas or O₂ gas to react with the adsorbed Mo precursor to form a molybdenum oxide (MoOₓ) layer, and a process of purging with N₂ gas or the like is repeated a predetermined number of times.

In FIG. 2, the horizontal axis represents the film forming temperature, and the vertical axis represents the film thickness of the MoOₓ layer. Each circle (◯) on the graph indicates a plot of the film thickness of the MoOₓ layer versus the film forming temperature when the ICL 200 was formed by supplying the Mo raw material and O₃ gas by the ALD method. Each triangle (Δ) indicates a plot of the film thickness of the MoOx layer versus the film forming temperature when the ICL 200 was formed by supplying the Mo raw material and O₂ gas by the ALD method.

The MoOₓ layer produced under the film forming conditions in region A of the graph in FIG. 2 was in an amorphous state, whereas the MoOₓ layer produced under the film forming conditions in other regions was crystallized. The MoOₓ layer produced under the deposition conditions of region A was crystallized in the subsequent annealing, and the morphology was improved at that time. Since the MoOₓ layer produced under the film forming conditions in other regions was crystallized before the annealing, the morphology was not improved even by the annealing.

From the above experimental results, it was found that it is important to select film forming conditions that allow the formation of an amorphous MoOₓ layer, and to form the amorphous MoOₓ layer under those film forming conditions. By forming the amorphous MoOx layer, the morphology of the MoOₓ layer (ICL) can be improved in the subsequent annealing, and leakage current of the capacitor can be reduced.

In addition, from the experimental results, under the film forming conditions that allow the formation of an amorphous MoOₓ layer, good results were obtained when the film forming temperature was higher than about 150 degrees C. and lower than about 350 degrees C. For example, in the range of 200 degrees C. to about 300 degrees C., it was easier to form an amorphous MoOₓ layer by using O₂ gas than by using O₃ gas. In addition, although not illustrated, when the film forming temperature was set to 200 degrees C. or less (e.g., 170 degrees C.), it was possible to form an amorphous MoOₓ layer by using either O₂ gas or O₃ gas.

Further, under the film forming conditions that allow the formation of an amorphous MoOₓ layer shown in region A, the film forming rate was higher when using O₃ gas than when using O₂ gas. It is thought that since O₃ gas has a higher oxidizing power than O₂ gas, the time for oxidizing (reacting with) Mo to MoOₓ can be shortened, and the film forming rate of the MoOₓ layer increases. On the other hand, O₃ gas is more likely to damage the base layer than O₂ gas.

Therefore, it is desirable to use O₂ gas directly on the base layer to form the MoOₓ layer without damaging the base layer. From the experimental results shown in FIG. 2, when the film forming temperature is in a range of about 200 degrees C. to about 300 degrees C., it is possible to implement the formation of an amorphous MoOₓ layer by using a Mo raw material and O₂ gas. In addition, when the film forming temperature is in a range of about 170 degrees C. to about 210 degrees C., it is possible to implement both the formation of an amorphous MoOₓ layer by using a Mo raw material and O₂ gas, and the formation of an amorphous MoOₓ layer by using a Mo raw material and O₃ gas.

In the present experiment, zirconium oxide (ZrO₂) was used as the base layer. The zirconium oxide base layer remained in an amorphous state even when a MoOₓ layer (ICL) was formed at a temperature of 300 degrees C. Therefore, when the film forming temperature of the MoOₓ layer is controlled to 300 degrees C. or lower, an amorphous MoOₓ layer can be formed without crystallizing the zirconium oxide base layer.

From the above, in the ICL 200 film forming method to be described below, an ICL 200 is formed by using film forming conditions that enable implementation of both the formation of an amorphous MoOₓ layer using a Mo raw material and O₂ gas and the formation of an amorphous MoOₓ layer using a Mo raw material and O₃ gas.

### [ICL Film Forming Method/Semiconductor Device Manufacturing Method]

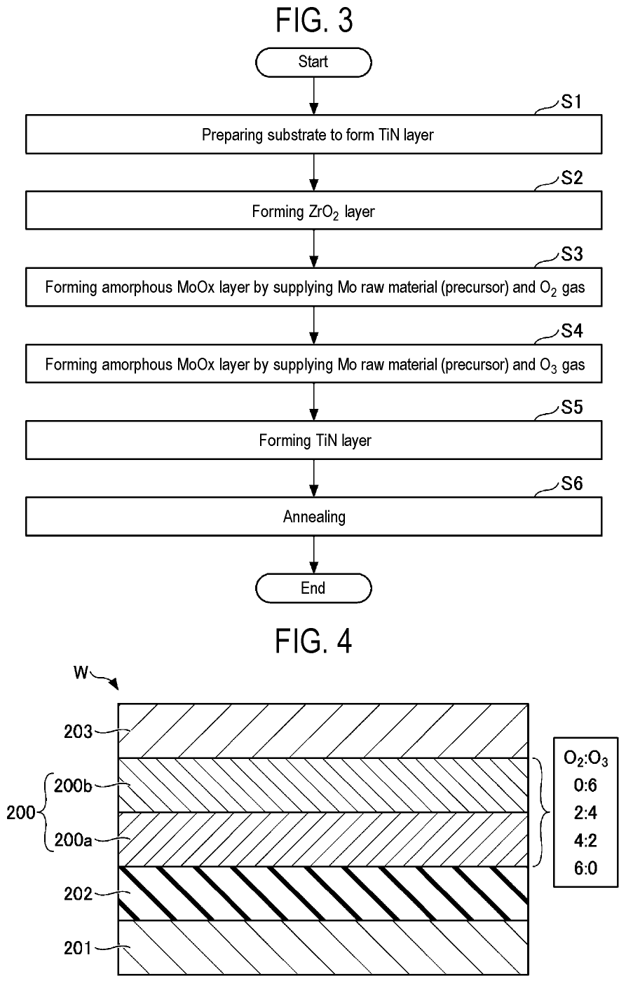

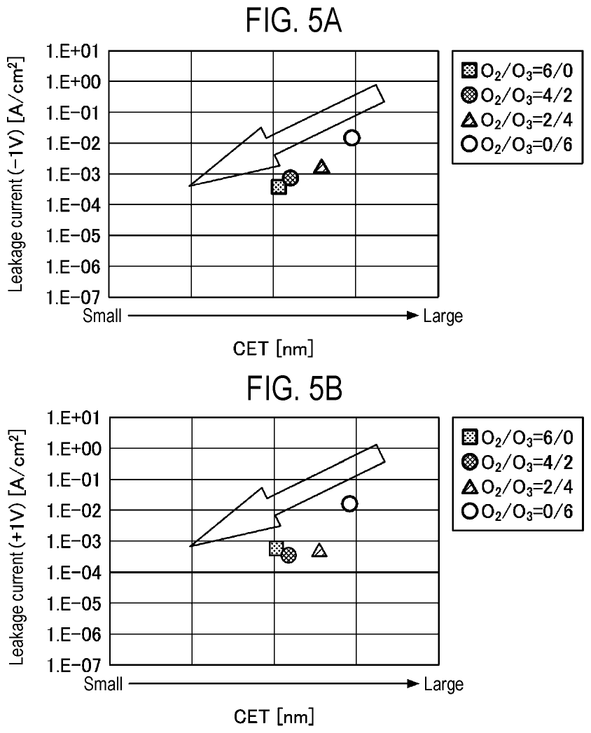

Hereinafter, a method of manufacturing a semiconductor device according to an embodiment will be described with reference to FIGS. 3 and 4. FIG. 3 is a flowchart illustrating an example of a method of manufacturing a semiconductor device including a method for forming an ICL film according to an embodiment. FIG. 4 is a view illustrating an example of a semiconductor device according to an embodiment.

### (Step S1)

When the process illustrated in FIG. 3 is initiated, in step S1, a substrate is prepared within a processing apparatus to be described later, and a TiN film is formed on the substrate W. For example, a TiN is formed on the substrate W by the ALD method by alternately supplying TiCl₄ gas and a reaction gas (NH₃ gas or N₂ gas). As a result, first, the lowermost TiN layer 201 illustrated in FIG. 4 is formed. Step S1 is an example of a process of forming a first metal-containing layer on the substrate, and the TiN layer 201 is an example of the first metal-containing layer. In step S1, methods such as a physical vapor deposition (PVD) and a chemical vapor deposition (CVD) may be used without being limited to the ALD method.

### (Step S2)

Next, in step S2, a ZrO₂ film is formed. For example, the ZrO₂ film is formed by heat treatment by supplying an organic zirconium gas and a reaction gas (e.g., O₃ gas). As a result, a ZrO₂ layer 202 is formed on the TiN layer 201, as illustrated in FIG. 4. Step S2 is an example of a process of forming a dielectric layer on the first metal-containing layer, and the ZrO₂ layer 202 is an example of the dielectric layer. In step S2, the PVD method and the CVD method may be used without being limited to the ALD method.

### (Step S3)

Next, in step S3, an amorphous MoOₓ film is formed by using a Mo raw material (Mo precursor) and O₂ gas by, for example, the ALD method. The film forming conditions in step S3 will be described later. As a result, a MoOₓ layer 200a is formed on the ZrO₂ layer 202, as illustrated in FIG. 4. Step S3 is an example of a process of supplying a first metal-containing precursor and a first oxygen gas to form a first metal oxide layer on the dielectric layer, and the MoOₓ layer 200a is an example of a first metal oxide layer. O₂ gas is an example of the first oxygen gas. The Mo precursor is an example of a first metal-containing precursor.

### (Step S4)

Next, in step S4, an amorphous MoOₓ film is formed by using a Mo raw material (Mo precursor) and O₃ gas by, for example, the ALD method. The film forming conditions in step S4 will be described later. As a result, as illustrated in FIG. 4, a MoOₓ layer 200b is formed on the MoOₓ layer 200a. Step S4 is an example of a process of supplying a second metal-containing precursor and a second oxygen gas different from the first oxygen gas to form a second metal oxide layer on the first metal oxide layer, and the MoOₓ layer 200b is an example of the second metal oxide layer. O₃ gas is an example of the second oxygen gas. An amorphous ICL 200 is formed by a laminated film of the MoOₓ layer 200a and the MoOₓ layer 200b on the MoOₓ layer 200a. The Mo precursor is an example of a second metal-containing precursor.

### (Step S5)

Next, in step S5, a TiN film is formed on the MoOₓ layer 200b by using a Ti raw material (third metal-containing precursor) and a reaction gas. For example, the TiN film is formed by the PVD by irradiating a Ti target with reactive ions (nitrogen ions). As a result, as illustrated in FIG. 4, a TiN layer 203 is formed as the uppermost layer. Step S5 is an example of a process of forming a second metal-containing layer on the second metal oxide layer, and the TiN layer 203 is an example of the second metal-containing layer. In step S5, the TiN film may be formed by the ALD method or the CVD method by supplying a Ti raw material (TiCl₄ gas) and a reaction gas (NH₃ or N₂) without being limited to the PVD method.

### (Step S6)

Next, in step S6, the temperature of the substrate or the temperature of the stage is controlled to a high temperature (e.g., 430 degrees C.), and N₂ gas is supplied to execute annealing. As a result, by crystallizing the ZrO₂ layer 202 and the ICL 200 (MoOₓ layer 200a and MoOₓ layer 200b), the morphology of the ICL 200 can be reduced and leakage current can be reduced.

### [ICL Film Forming Method: Steps S3 and S4]

A method of forming the ICL 200 (MoOₓ layer) in steps S3 and S4 will be described. In step S3, the MoOₓ layer 200a is formed by executing, a predetermined number of times (referred to as “m times”), a first cycle in which the Mo raw material and the O₂ gas are alternately supplied.

In step S4, the MoOₓ layer 200b is formed by executing, a predetermined number of times (referred to as “n times”), a second cycle in which the Mo raw material and the O₃ gas are alternately supplied.

The number of repetitions m of the first cycle is one or more. The number of repetitions n of the second cycle is one or more. The number of times m and the number of times n may be the same number or different numbers. The ratio between the first cycle and the second cycle may be 6:0 to 1:5.

The temperature of the stage or the temperature of the substrate when forming each of the MoOₓ layer 200a and the MoOₓ layer 200b is preferably in a range of 150 degrees C. to 210 degrees C. As a result, the amorphous MoOₓ layer 200a and MoOₓ layer 200b can be formed.

The Mo raw material (Mo precursor) supplied in step S3 and the Mo raw material (Mo precursor) supplied in step S4 may be the same raw material or may be different raw materials. As the Mo raw material, for example, a bis(alkylimide)-bis(alkylamido)molybdenum compound is disclosed. The bis(alkylimido)-bis(alkylamido)molybdenum compound has the formula Mo(NR)₂(NHR′)₂ (wherein R and R′ are independently selected from the group consisting of C₁ to C₄ alkyl groups, C₁ to C₄ perfluoroalkyl groups, and alkylsilyl groups).

The Mo precursor may be an organic molybdenum precursor such as an alkylaminomolybdenum compound. The Mo precursor is an example of the first metal-containing precursor and the second metal-containing precursor. Each of the first metal-containing precursor and the second metal-containing precursor may contain at least one metal selected from Mo, Nb, Ti, and Ta.

The MoOₓ layer 200a is an example of the first metal oxide layer. The MoOₓ layer 200b is an example of the second metal oxide layer. Each of the first metal oxide layer and the second metal oxide layer may contain at least one metal selected from Mo, Nb, Ti, and Ta. The ratio between the film thicknesses of the first metal oxide layer and the second metal oxide layer may be 6:0 to 1:5. The thickness of the second metal oxide layer may be smaller than the thickness of the first metal oxide layer.

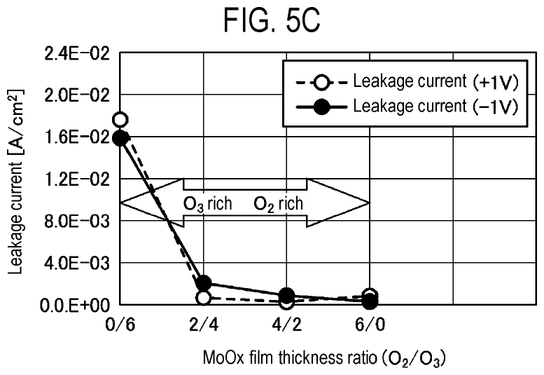

FIGS. 5A to 5C are diagrams illustrating examples of effects of an ICL film forming method according to an embodiment. FIGS. 5A to 5C show examples of the results obtained by measuring leakage current generated in a structure on a substrate W (see FIG. 4) after the annealing in step S6 of FIG. 3. The vertical axis in FIG. 5A represents the leakage current that flows when a voltage of −1 V (volt) is applied between the upper and lower electrodes of the structure (between the TiN layers 201 and 203 in FIG. 4). The vertical axis in FIG. 5B represents the leakage current that flows when a voltage of +1 V is applied between the upper and lower electrodes of the structure. The capacitive equivalent thickness (CET) represented on the horizontal axes in FIGS. 5A and 5B indicates the thickness of a formed ICL 200 when electrically converted to correspond to the dielectric constant of a SiO₂ film. A smaller CET indicates that the ICL 200 has higher performance.

In FIGS. 5A and 5B, O₂/O₃ indicates the film thickness ratio between the MoOₓ layer 200a and the MoOₓ layer 200b illustrated in FIG. 4. When O₂/O₃=6/0, the film thickness ratio between the MoOₓ layer 200a and the MoOₓ layer 200b is 6:0, indicating that the entire layer is formed as the MoOₓ layer 200a and there is no MoOₓ layer 200b. When O₂/O₃=4/2 or 2/4, it indicates that the MoOₓ layer 200a has a thickness twice or half that of the MoOₓ layer 200b. When O₂/O₃=0/6, the entire layer is formed as the MoOₓ layer 200b, and there is no MoOₓ layer 200a.

In the experimental results, FIGS. 5A and 5B showed almost the same effect. As the MoOₓ layer 200a has a greater thickness relative to the MoOₓ layer 200b, the leakage current is reduced, so that the CET was small, and the performance of the ICL 200 was high.

In FIG. 5C, the horizontal axis represents the thickness ratio (O₂/O₃) of the MoOₓ layer 200a to the MoOₓ layer 200b. The vertical axis represents the leakage current that flows when voltages of +1 V and −1 V are applied between the upper and lower electrodes of the structure. When O₂/O₃ is 0/6, it indicates that only the MoOₓ layer 200b is formed without the MoOₓ layer 200a. When O₂/O₃ is 6/0, it indicates that only the MoOₓ layer 200a is formed without the MoOₓ layer 200b. From the experimental results illustrated in FIG. 5C, the leakage current was the highest when O₂/O₃ is 0/6, that is, when only the MoOₓ layer 200b was formed (when only O₃ gas was used for film formation). In other cases, that is, when O₂/O₃ was 2/4, 4/2, or 6/0, it was possible to reduce the leakage current.

Therefore, as the thickness of the MoOₓ layer 200a formed with O₂ gas was increased, the leakage current was reduced, and the electrical characteristics of the ICL 200 were improved. Furthermore, as described above, at the interface with the ZrO₂ layer 202 (the base layer), when O₂ gas is used to form the MoOₓ layer, the damage to the ZrO₂ layer 202 is less, but the film forming rate is slow. On the other hand, when O₃ gas is used to form the MoOₓ layer, the damage to the ZrO₂ layer 202 is greater, but the film forming rate is fast.

Therefore, the thickness of the MoOₓ layer 200b may be smaller than the thickness of the MoOₓ layer 200a and larger than 0. In addition, the thickness of the MoOₓ layer 200b may be greater than the thickness of the MoOₓ layer 200a. The ratio between the film thicknesses of the MoOₓ layer 200a and the MoOₓ layer 200b may be 6:0 to 1:5. This makes it possible to increase the MoOₓ film forming rate and improve throughput while reducing leakage current. Furthermore, by forming the MoOₓ layer 200b on the MoOₓ layer 200a, the damage to the base layer can be suppressed.

### [Other Steps]

### (ZrO₂ Layer: Step S2)

The ZrO₂ layer 202 formed in step S2 of FIG. 4 is an example of a dielectric layer. The dielectric layer may be a metal-containing oxide or a metal-containing oxynitride. The metal-containing oxide or metal-containing oxynitride may contain at least one metal selected from Hf, Zr, Pr, Nd, Gd, Dy, Yb, Pb, Zn, Ti, or Lu.

### (TiN Layer: Step S5)

The TiN layer 203 formed in step S5 of FIG. 4 is an example of a metal-containing layer (second metal-containing layer) formed on the second metal oxide layer. The metal-containing layer (second metal-containing layer) may be a nitride containing at least one metal selected from Ta, W, Al, or Ti.

In step S1 of FIG. 4 as well, the TiN layer 201 may be formed by using the same method as the method of forming the TiN layer 203 in step S5.

### [Capacitor]

The semiconductor device manufactured by the semiconductor device manufacturing method of FIG. 3 (the structure on the substrate W illustrated in FIG. 4) may be a capacitor. The capacitor includes a first electrode, a second electrode disposed to be spaced apart from the first electrode, a dielectric layer disposed between the first electrode and the second electrode, and an interface layer disposed between the second electrode and the dielectric layer.

The TiN layer 201 is an example of the first electrode, the TiN layer 203 is an example of the second electrode disposed to be spaced apart from the first electrode, and the ZrO₂ layer 202 is an example of the dielectric layer disposed between the first electrode and the second electrode.

The ICL 200 is an example of the interface layer disposed between the second electrode and the dielectric layer. The interface layer includes a first interface layer formed by supplying a metal-containing precursor and a first oxygen gas, and a second interface layer formed by supplying a metal-containing precursor and a second oxygen gas different from the first oxygen gas. The second interface layer is disposed over the first interface layer.

The MoOₓ layer 200a has a first thickness and is an example of the first interface layer formed by supplying the metal-containing precursor and the first oxygen gas. The MoOₓ layer 200b has a second thickness smaller than the first thickness and is an example of the second interface layer formed by supplying a metal-containing precursor and the second oxygen gas different from the first oxygen gas.

### [Processing System]

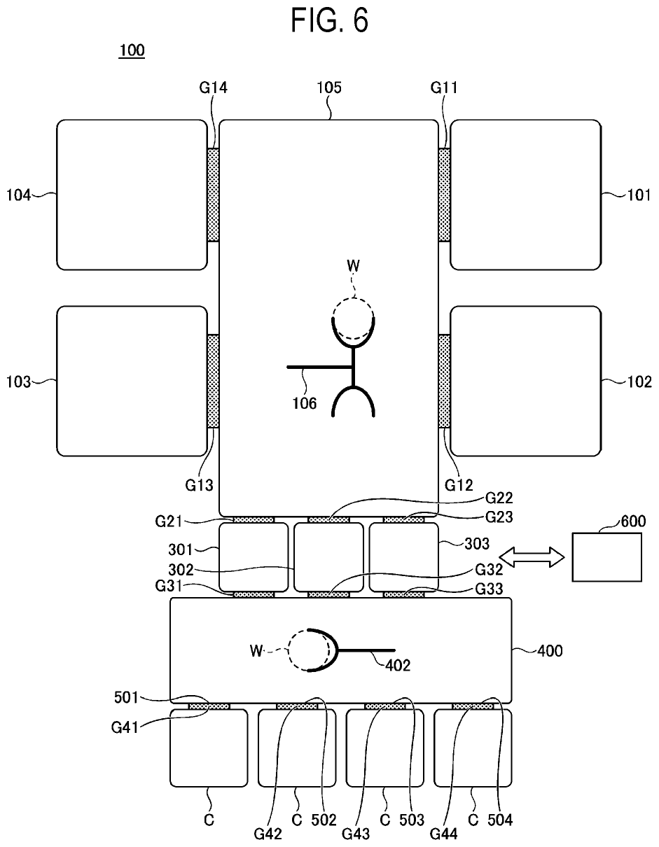

Next, an example of a processing system 100 for manufacturing a semiconductor device using the semiconductor device manufacturing method illustrated in FIG. 3 will be described with reference to FIG. 6. FIG. 6 is a view illustrating an example of the processing system 100 according to an embodiment.

The processing system 100 includes processing apparatuses 101 to 104, a vacuum transfer chamber 105, load-lock chambers 301 to 303, an atmospheric transfer chamber 400, load ports 501 to 504, and a controller 600.

The processing apparatuses 101 to 104 are connected to the vacuum transfer chamber 105 via respective gate valves G11 to G14. The interiors of the processing apparatuses 101 to 104 are depressurized to a predetermined vacuum atmosphere, and desired processes are performed on wafers W therein.

The processing apparatus 101 executes step S1 in FIG. 3 to alternately supply TiCl₄ gas and a reaction gas (ammonia gas or N₂ gas) into a processing container of the processing apparatus 101 to form the TiN layer 201 on a substrate W by the ALD method. In addition, the processing apparatus 101 executes step S5 in FIG. 3 to irradiate the Ti target with reactive ions to form a TiN layer 203 on the ICL 200 by, for example, the PVD method. The processing apparatus 101 is an example of a first processing apparatus that forms a first metal-containing layer and a second metal-containing layer on a substrate.

The processing apparatus 102 executes step S2 in FIG. 3 to supply an organic zirconium source gas and a reaction gas (O₃ gas) to form the ZrO₂ layer 202 on the TiN layer 201. The processing apparatus 102 is an example of a second processing apparatus that forms a dielectric layer on a substrate.

The processing apparatus 103 executes steps S3 and S4 in FIG. 3 to form the MoOₓ layer 200a and the MoOₓ layer 200b. In step S3, a Mo raw material and O₂ gas are alternately supplied into a processing container of the processing apparatus 103 to form the MoOₓ layer 200a by the ALD method. After executing step S3, in step S4, the oxygen gas is switched from O₂ gas to O₃ gas), and the Mo raw material and O₃ gas are alternately supplied into the processing container of the processing apparatus 103 to form the MoOₓ layer 200b by the ALD method. The processing apparatus 103 is an example of a third processing apparatus that forms a first metal oxide layer on a dielectric layer by supplying a metal-containing precursor and a first oxygen gas, and that forms a second metal oxide layer on the first metal oxide layer by switching to a second oxygen gas different from the first oxygen gas.

The processing apparatus 104 executes step S6 in FIG. 3 to supply N₂ gas into a processing container of the processing apparatus 104, and anneals the formed structure of the TiN layer 201, the ZrO₂ layer 202, the ICL 200 (MoOₓ layer 200a and MoOₓ layer 200b), and the TiN layer 203 at a high temperature (e.g., about 430 degrees C.). This crystallizes the amorphous ZrO₂ layer 202 and ICL 200. As a result, the morphology of the ICL 200 can be reduced, and leakage current can be reduced. The processing apparatus 104 is a fourth processing apparatus that anneals the first metal-containing layer, the second metal-containing layer, the dielectric layer, the first metal oxide layer, and the second metal-containing layer formed in the first processing apparatus, the second processing apparatus, and the third processing apparatus.

An interior of the vacuum transfer chamber 105 is depressurized to a predetermined vacuum atmosphere. The vacuum transfer chamber 105 is an example of a transfer apparatus that transfers substrates. The vacuum transfer chamber 105 is provided with a transfer mechanism 106 capable of transferring substrates W in the depressurized state. The transfer mechanism 106 transfers substrates W to the processing apparatuses 101 to 104 and the load-lock chambers 301 to 303.

The load-lock chambers 301 to 303 are connected to the vacuum transfer chamber 105 via gate valves G21 to G23, respectively, and connected to the atmospheric transfer chamber 400 via the gate valves G31 to G33, respectively. Interiors of the load-lock chambers 301 to 303 are configured to be switchable between an air atmosphere and a vacuum atmosphere.

An interior of the atmospheric transfer chamber 400 is an air atmosphere and, for example, a downflow of clean air is formed in the atmospheric transfer chamber 400. In the atmospheric transfer chamber 400, an aligner (not illustrated) is provided to perform alignment of substrates W. In addition, the atmospheric transfer chamber 400 is provided with a transfer mechanism 402. In addition, the transfer mechanism 402 transfers substrates W to the load-lock chambers 301 to 303, to carriers C in the load ports 501 to 504 to be described later, and to the aligner.

The load ports 501 to 504 are provided in a wall of the atmospheric transfer chamber 400. In each of the load ports 501 to 504, a carrier C accommodating substrates W or an empty carrier C is placed through a corresponding one of the gate valves G41 to G44. As the carriers C, for example, front opening unified pods (FOUPs) may be used.

The controller 600 controls each component of the processing system 100. For example, the controller 600 executes the operations of the processing apparatuses 101 to 104, the operations of the transfer mechanisms 106 and 402, the opening/closing of the gate valves G11 to G14, G21 to G23, G31 to G33, and G41 to G44, the switching of the atmospheres in the load-lock chambers 301 to 303, and the like.

### [Processing Apparatus]

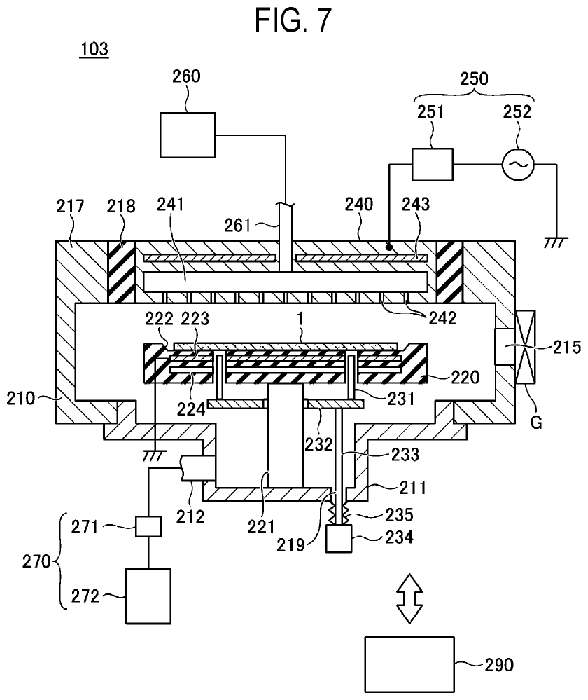

An example of the processing apparatus 103 arranged in the processing system 100 to form an ICL 200 will be described with reference to FIG. 7. FIG. 7 is a view illustrating an example of the substrate processing apparatus 103 according to an embodiment.

The processing apparatus 103 includes a substantially cylindrical airtight processing container 210. An exhaust chamber 211 is provided in a central portion of a bottom wall of the processing container 210. The exhaust chamber 211 has, for example, a substantially cylindrical shape that protrudes downward. An exhaust pipe 212 is connected to the exhaust chamber 211, for example, on a side surface of the exhaust chamber 211.

An exhaust source 272 is connected to the exhaust pipe 212 via a pressure controller 271. The pressure controller 271 includes a pressure regulating valve such as a butterfly valve. The exhaust pipe 212 is configured such that the pressure inside the processing container 210 can be reduced by the exhaust source 272. The pressure controller 271 and the exhaust source 272 constitute a gas discharge mechanism 270 configured to discharge the gas inside the processing container 210. A transfer port 215 is provided on a side surface of the processing container 210. The transfer port 215 is opened/closed by a gate valve G.

A stage 220 as a holder configured to hold a substrate 1 is provided in the processing container 210. The stage 220 holds the substrate 1 in a horizontal posture. The stage 220 has a substantially circular shape in a plan view and is supported by a support member 221. On the surface of the stage 220, a substantially circular recess 222 for placing, for example, a substrate 1 having a diameter of 300 mm may be formed. The recess 222 has an inner diameter slightly larger than the diameter of the substrate 1. The depth of the recess 222 is substantially the same as, for example, the thickness of the substrate 1. The stage 220 is made of a ceramic material such as aluminum nitride (AlN). The stage 220 may be made of a metal material such as nickel (Ni). A guide ring configured to guide the substrate 1 may be provided on the peripheral edge of the surface of the stage 220 instead of the recess 222.

For example, a grounded lower electrode 223 is embedded in the stage 220. A heater 224 is embedded below the lower electrode 223. The heater 224 heats the substrate 1 placed on the stage 220 to a set temperature by receiving power from a power supply (not illustrated) based on a control signal from a controller 290. When the entire stage 220 is made of metal, the entire stage 220 functions as a lower electrode, so that the lower electrode 223 does not have to be embedded in the stage 220. The stage 220 is provided with a plurality of (e.g., three) pins 231 configured to hold and raise/lower the substrate 1 placed on the stage 220. The material of the pins 231 may be, for example, ceramic such as alumina (Al₂O₃), quartz, or the like. The lower ends of the pins 231 are installed on a support plate 232. The support plate 232 is connected to a lifting mechanism 234 provided outside the processing container 210 via a lifting shaft 233.

The lifting mechanism 234 is installed, for example, under the exhaust chamber 211. A bellows 235 is provided between an opening 219 for the lifting shaft 233 formed in the bottom surface of the exhaust chamber 211 and the lifting mechanism 234. The support plate 232 may have a shape that can be raised/lowered without interfering with the support member 221 of the stage 220. The pins 231 are configured to be raised/lowered by the lifting mechanism 234 between the upper side of the surface of the stage 220 and the lower side of the surface of the stage 220.

A gas supplier 240 is provided on a ceiling wall 217 of the processing container 210 via an insulating member 218. The gas supplier 240 constitutes an upper electrode and faces the lower electrode 223. A radio-frequency power supply 252 is connected to the gas supplier 240 via a matcher 251. By supplying radio-frequency power of 450 kHz to 100 MHz from the radio-frequency power supply 252 to the upper electrode (the gas supplier 240), a radio-frequency electric field is generated between the upper electrode (the gas supplier 240) and the lower electrode 223, and capacitively coupled plasma is generated. A plasma generator 250 configured to generate plasma includes the matcher 251 and the radio-frequency power supply 252. The plasma generator 250 is not limited to capacitively coupled plasma and may generate other plasma such as inductively coupled plasma.

The gas supplier 240 includes a hollow gas supply chamber 241. In a bottom surface of the gas supply chamber 241, a large number of holes 242 configured to distribute and supply a processing gas into the processing container 210 are arranged, for example, evenly. A heater 243 is embedded in the gas supplier 240, for example, above the gas supply chamber 241. The heater 243 is heated to a set temperature by being fed with power from a power supply (not illustrated) based on a control signal from the controller 290.

A gas supply mechanism 260 is connected to the gas supply chamber 241 via a gas supply path 261. The gas supply mechanism 260 supplies the gases used in at least one of step S3 or step S4 in FIG. 3 to the gas supply chamber 241 via the gas supply path 261. Although not illustrated, the gas supply mechanism 260 includes, for each type of gas, an individual pipe, an opening/closing valve provided in the middle of the individual pipe, and a flow controller provided in the middle of the individual pipe. When the opening/closing valve opens the individual pipe, a gas is supplied from a supply source to the gas supply path 261. The supply amount of the gas is controlled by the flow rate controller. On the other hand, when the opening/closing valve closes the individual pipe, the supply of the gas from the supply source to the gas supply path 261 stops.

The controller 290 controls each component of the processing apparatus 103. The controller 290 controls the type of the gas, a flow rate of the gas, the temperature of the substrate (the temperature of the stage), a processing time, and the like so as to execute steps S3 and S4 in FIG. 3.

Further, the processing apparatuses 101, 102, and 104 may have same configurations as the configuration of the processing apparatus 103, or have a configuration different from the configuration of the processing apparatus 103. The descriptions of the configurations of the processing apparatuses 101, 102, and 104 are omitted. The above-described processing apparatuses 101 to 104 may be applied to one of a single-wafer apparatus that processes substrates one by one, a batch apparatus that processes multiple substrates at once, or a semi-batch apparatus. The processing apparatus 101 to 104 may be an apparatus that processes a substrate without using plasma, or may be an apparatus that process a substrate using plasma.

According to an aspect, leakage current can be reduced.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
preparing a substrate on which a dielectric layer is formed in a processing container;
forming a first metal oxide layer on the dielectric layer by supplying a first metal-containing precursor and a first oxygen gas; and
forming a second metal oxide layer on the first metal oxide layer by supplying a second metal-containing precursor and a second oxygen gas different from the first oxygen gas.

2. The film forming method of claim 1, wherein the first metal oxide layer and the second metal oxide layer are amorphous films.

3. The film forming method of claim 1, wherein the first metal oxide layer is formed by a first cycle in which alternately supplying the first metal-containing precursor and the first oxygen gas is repeated a first predetermined number of times, and
wherein the second metal oxide layer is formed by a second cycle in which alternately supplying the second metal-containing precursor and the second oxygen gas is repeated a second predetermined number of times.

4. The film forming method of claim 3, wherein a ratio between the first cycle and the second cycle is 6:0 to 1:5.

5. The film forming method of claim 1, wherein a ratio between film thicknesses of the first metal oxide layer and the second metal oxide layer is 6:0 to 1:5.

6. The film forming method of claim 5, wherein the second metal oxide layer has the film thickness smaller than the film thickness of the first metal oxide layer.

7. The film forming method of claim 1, wherein the first oxygen gas is O₂ gas, and the second oxygen gas is O₃ gas.

8. The film forming method of claim 1, wherein each of the first metal-containing precursor and the second metal-containing precursor contains at least one metal selected from Mo, Nb, Ti, or Ta.

9. The film forming method of claim 1, wherein each of the first metal oxide layer and the second metal oxide layer contains at least one metal selected from Mo, Nb, Ti, or Ta.

10. The film forming method of claim 1, wherein the dielectric layer is one of a metal-containing oxide or a metal-containing oxynitride.

11. The film forming method of claim 10, wherein the metal-containing oxide or the metal-containing oxynitride contains at least one metal selected from Hf, Zr, Pr, Nd, Gd, Dy, Yb, Pb, Zn, Ti, or Lu.

12. The film forming method of claim 1, wherein a stage on which the substrate is placed or the substrate has a temperature in a range of 150 degrees C. to 210 degrees C. when forming each of the first metal oxide layer and the second metal oxide layer.

13. The film forming method of claim 1, further comprising:
forming a metal-containing layer on the second metal oxide layer by supplying a third metal-containing precursor and a reaction gas.

14. The film forming method of claim 13, wherein the metal-containing layer is a nitride containing at least one metal selected from Ta, W, Al, or Ti.

15. A method of manufacturing a semiconductor device, the method comprising:
forming a first metal-containing layer on a substrate;
forming a dielectric layer on the first metal-containing layer;
forming a first metal oxide layer on the dielectric layer by supplying a first metal-containing precursor and a first oxygen gas;
forming a second metal oxide layer on the first metal oxide layer by supplying a second metal-containing precursor and a second oxygen gas different from the first oxygen gas; and
forming a second metal-containing layer on the second metal oxide layer.

16. The method of claim 15, wherein the second metal oxide layer has a film thickness smaller than a film thickness of the first metal oxide layer.

17. The method of claim 16, further comprising:
annealing the first metal-containing layer, the dielectric layer, the first metal oxide layer, the second metal oxide layer, and the second metal-containing layer.

18. A processing system comprising:
a first processing apparatus;
a second processing apparatus;
a third processing apparatus; and
a transfer apparatus configured to transfer a substrate and connected to the first to third processing apparatuses,
wherein the first processing apparatus is configured to form a first metal-containing layer and a second metal-containing layer on the substrate,
wherein the second processing apparatus is configured to form a dielectric layer on the substrate, and
wherein the third processing apparatus is configured to form a first metal oxide layer on the dielectric layer by supplying a metal-containing precursor and a first oxygen gas and to form a second metal oxide layer on the first metal oxide layer by switching to a second oxygen gas different from the first oxygen gas.

19. The processing system of claim 18, further comprising:
a fourth processing apparatus,
wherein the fourth processing apparatus is configured to anneal the first metal-containing layer, the second metal-containing layer, the dielectric layer, the first metal oxide layer, and the second metal oxide layer formed by the first processing apparatus, the second processing apparatus, and the third processing apparatus.
